(19) United States
(12) Patent Application Publication
(10) Pub. No.: US 2025/0069968 A1
(43) Pub. Date: Feb. 27, 2025

(54) SEMICONDUCTOR DEVICE, METHOD FOR FABRICATING THE SAME

(71) Applicant: LAPIS Semiconductor Co., Ltd., Yokohama-shi (JP)

(72) Inventors: Shohei HIEJIMA, Yokohama-shi (JP); Hiroshi KAWANO, Yokohama-shi (JP); Hidetoshi YANAGITA, Yokohama-shi (JP)

(73) Assignee: LAPIS Semiconductor Co., Ltd., Yokohama-shi (JP)

(21) Appl. No.: 18/812,910

(22) Filed: Aug. 22, 2024

(30) Foreign Application Priority Data
Aug. 24, 2023 (JP) 2023-136637

(51) Int. Cl. H01L 23/14; H01L 23/08

(52) U.S. Cl. CPC H01L 23/145; H01L 23/08

(57) ABSTRACT

A semiconductor device includes: a supporting body having first and second principal faces, and semiconductor elements; a thin film metal electrode on the first principal face; a thick film metal body on the thin film metal electrode; and a resin structure on the supporting body. The thick film metal body has a thickness greater than that of the thin film metal electrode. The resin structure includes a first resin body that covers a side of the thick film metal body. The resin structure has at least one of structures 1 and 2 as follows: in the structure 1, the resin structure further includes a second resin body on the second principal face; and in the structure 2, the first resin body includes first and second regions on the first principal face, and the second region has a thickness greater than that of the first region.

### CROSS-REFERENCE TO RELATED APPLICATION

This application is based on and claims priority under 35 USC 119 from Japanese Patent Application to Japanese Patent Application No. 2023-136637 filed on Aug. 24, 2023, the disclosure of which are incorporated herein by reference.

### BACKGROUND

### Technical Field

The present disclosure relates to a semiconductor device and a method of fabricating the semiconductor device.

### Related Art

Japanese Patent Application Laid-Open (JP-A) No. 2016-146395 discloses minimizing the warpage of semiconductor devices, which are produced from the wafer product thereof by dicing. This fabricating method includes a first adhering step, a thinning step, a dividing step, a second adhering step, and a separating step. The first adhering step adheres a supporting plate to the first principal face of the wafer product, which mounts integrated circuits. After the first adhering step, the thinning step polishes or grinds the second principal face of the wafer product to make the wafer thin in thickness. In the dividing step, the wafer thus thinning is divided into multiple chip bodies. After the dividing step, the second adhesion step adheres a reinforcing layer to the second principal face of the multiple chip bodies. The second adhesion step is followed by the peeling process to peel off the supporting plate.

Warpage of the wafer, which is caused in the method for fabricating a semiconductor device, in particular, for use in a chip size package or chip scale package technology (hereinafter referred to as CSP structure), has an influence on various processes in the fabrication.

Recently, attention has been focused on large-sized semiconductor chips of CSP structures to reduce the warpage thereof. However, the warpage may be associated with not only the size of the semiconductor chips but also the size of the electrodes and thickness of the covering resin bodies of the semiconductor chips which are related to the CSP structures. Reducing the warpage of semiconductor devices of the CSP structures is desired independent of the size of semiconductor chips.

### SUMMARY

A first aspect of the present disclosure is a semiconductor device, which includes a supporting body having a first principal face, a second principal face opposite to the first principal face, and one or more semiconductor elements; at least one thin film metal electrode disposed on the first principal face of the supporting body; a thick film metal body disposed on the at least one thin film metal electrode; and a resin structure disposed on the supporting body, wherein the thick film metal body has a thickness greater than that of the thin film metal electrode, wherein the resin structure includes a first resin body that covers a side of the thick film metal body on the first principal face of the supporting body, and wherein the resin structure has at least one of structures 1 and 2 as follows: in the structure 1, the resin structure further includes a second resin body on the second principal face of the supporting body; and in the structure 2, the first resin body of the resin structure includes a first region and a second region on the first principal face of the supporting body, and the second region has a thickness greater than that of the first region.

A second aspect of the present disclosure is a method for fabricating a semiconductor device, which includes: preparing a base substrate including a semiconductor, the base substrate having a first principal face, a second principal face opposite to the first principal face, and an arrangement of multiple sections, and each of the multiple sections including semiconductor elements on the first principal face; forming a thin film metal electrode on the first principal face in each of the multiple sections of the base substrate; forming a thick metal film on the first principal face in each of the multiple sections of the base substrate to form a wafer product, the thick metal film being disposed on the thin film metal electrode; and forming a resin body on the base substrate of the wafer product, the resin body including at least one resin thick film, wherein a thickness of the thick film metal body is greater than that of the thin film metal electrode, wherein the resin body includes a first resin film that covers at least a side face of the thick film metal body on the first principal face of the base substrate, and wherein the resin body has at least one of structures 1 and 2 as follows: in the structure 1, the resin body further includes a second resin thick film disposed on the second principal face of the base substrate; and in the structure 2, the resin body provides the first resin thick film with a first region and a second region, a thickness of the second region is greater than that of the first region, the first and second regions are disposed on the first principal face of the base substrate such that the first region has a shape of at least one of a recess and a groove in the first resin thick film.

A third aspect of the present disclosure is a semiconductor device, which includes: a base substrate including a semiconductor region having a first principal face and a second principal face opposite to the first principal face, multiple sections arranged on the first principal face, and one or more semiconductor elements on the first principal face of the semiconductor region in each of the multiple sections; at least one thin film metal electrode disposed on the first principal face in each of the multiple sections; a thick film metal body disposed on the at least one thin film metal electrode in each of the multiple sections; and a resin body disposed on the first principal face over the multiple sections, wherein the thick film metal body has a thickness greater than that of the thin film metal electrode, wherein the resin body includes a first resin thick film that covers a side of the thick film metal body on the first principal face of the base substrate 41, wherein the resin body has at least one of structures 1 and 2 as follows: in the structure 1, the resin body further includes a second resin thick film disposed on the second principal face of the base substrate; and in the structure 2, the resin body provides the first resin thick film with a first region and a second region, the second region has a thickness greater than that of the first region, the first and second regions are arranged on the first principal face of the base substrate to form at least one of a recess and a groove in the first resin thick film.

### BRIEF DESCRIPTION OF THE DRAWINGS

Exemplary embodiments of the present disclosure will be described in detail based on the following figures, wherein:

FIG. 1 is a schematic perspective view showing an exemplary semiconductor device according to the present disclosure;

FIG. 2 is a plan view showing the semiconductor device according to the present disclosure;

FIG. 3 is a cross-sectional view, taken along line II-II shown in FIG. 2, showing the semiconductor device according to the present disclosure;

FIG. 4 is a cross-sectional view, taken along line III-III shown in FIG. 2, showing the semiconductor device according to the present disclosure;

FIG. 5 is a cross-sectional view showing a certain process in the method for fabricating a semiconductor device according to the present disclosure;

FIG. 6 is a cross-sectional view showing a certain process in the method for fabricating the semiconductor device according to the present disclosure;

FIG. 7 is a cross-sectional view showing a certain process in the method for fabricating the semiconductor device according to the present disclosure;

FIG. 8 is a cross-sectional view showing a certain process in the method for fabricating the semiconductor device according to the present disclosure;

FIG. 9 is a cross-sectional view showing a certain process in the method for fabricating the semiconductor device according to the present disclosure;

FIG. 10 is a cross-sectional view showing a certain process in the method for fabricating the semiconductor device according to the present disclosure;

FIG. 11 is a cross-sectional view showing a certain process in the method for fabricating the semiconductor device according to the present disclosure;

FIG. 12 is a cross-sectional view showing a certain process in the method for fabricating the semiconductor device according to the present disclosure;

FIG. 13 is a cross-sectional view showing a certain process in the method for fabricating the semiconductor device according to the present disclosure;

FIG. 14 is a cross-sectional view showing a certain process in the method for fabricating the semiconductor device according to the present disclosure;

FIG. 15 is a flow showing major processes in the method for fabricating the semiconductor device according to the present disclosure;

FIG. 16 is a plan view showing a wafer product and exemplary half-cut lines according to the present disclosure;

FIG. 17 is a plan view showing a wafer product according to the present disclosure;

FIG. 18 is a plan view showing a wafer product and a mold according to the present disclosure;

FIG. 19 is a schematic view showing exemplary processes in the method for fabricating the semiconductor device according to the present disclosure;

FIG. 20 is a schematic view showing exemplary processes in the method for fabricating the semiconductor device according to the present disclosure;

FIG. 21 is a schematic view showing exemplary processes in the method for fabricating the semiconductor device according to the present disclosure;

FIGS. 22A to 22D each show the size of the cavity of an exemplary mold used in the fabricating method according to the present disclosure;

FIGS. 23A to 23B are schematic views each showing exemplary widths of the half-cut region and separation region between the arrayed sections in the wafer product in the fabricating method according to the present disclosure;

FIGS. 24A to 24H are schematic views each showing an exemplary arrangement of a first region and a second region of a semiconductor device fabricated by the fabricating method according to the present disclosure; and

FIGS. 25A, 25B, 25C, and 25D are schematic views each showing a CSP assembly fabricated by the fabricating method according to the present disclosure.

### DETAILED DESCRIPTION

Hereinafter, embodiments for carrying out the present disclosure will be described with reference to the figures. In the following description, the same parts will be denoted by the same reference numerals to omit duplicated description.

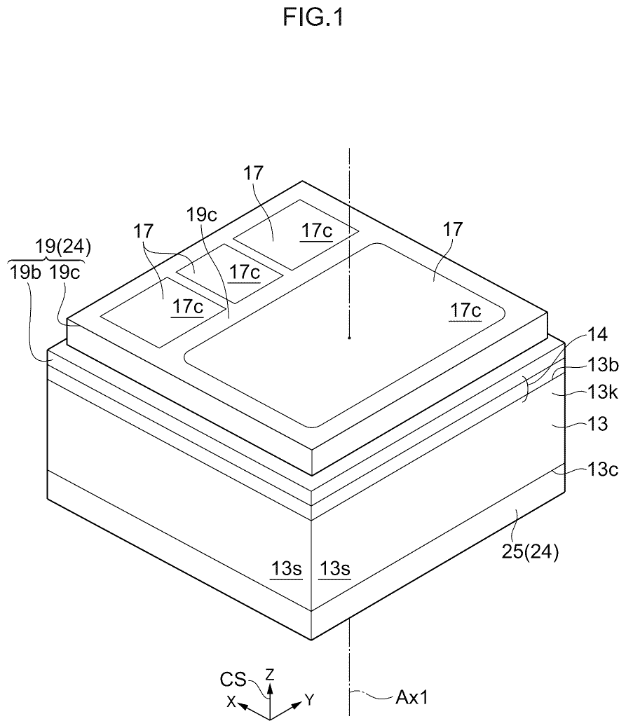

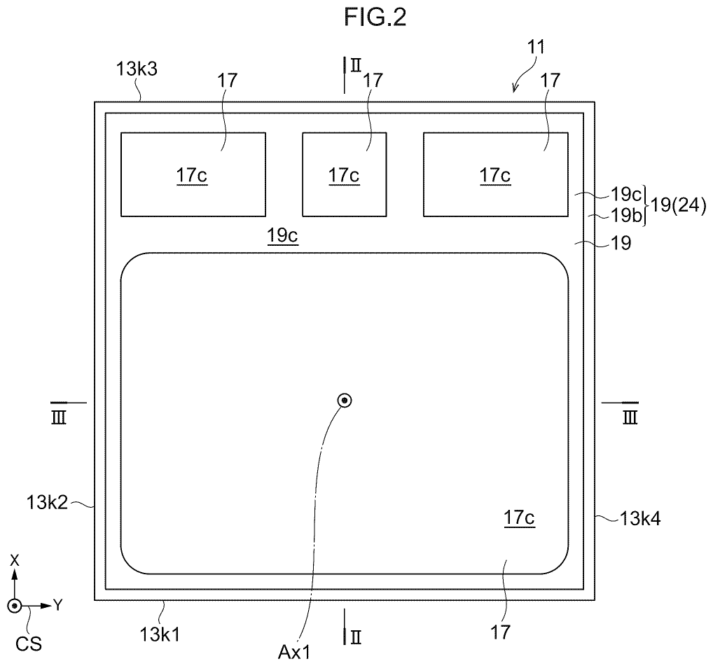

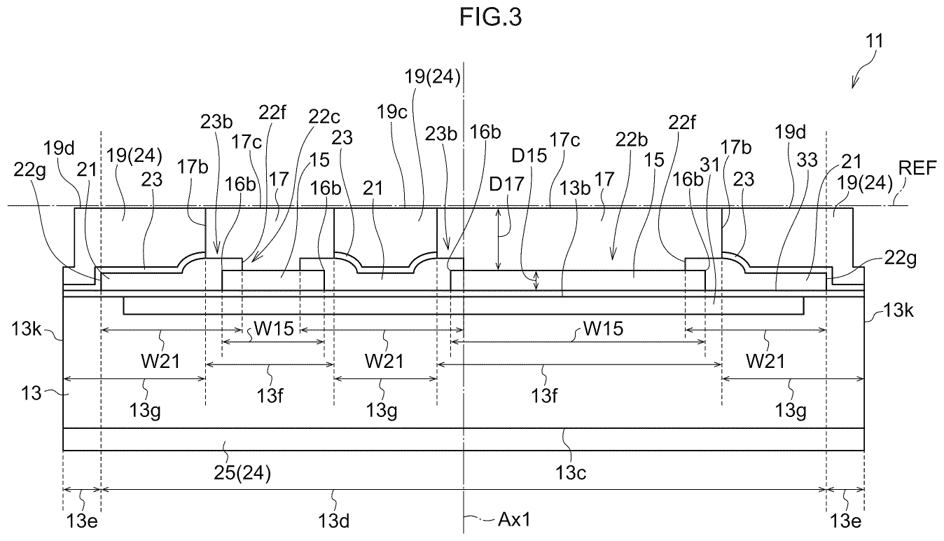

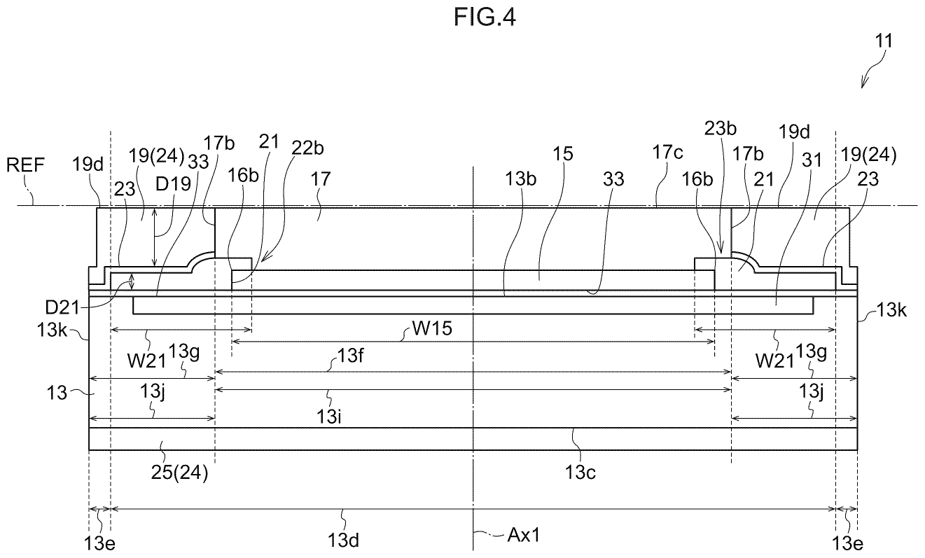

FIG. 1 is a schematic view showing the structure of a semiconductor device according to the present disclosure. FIG. 2 is a schematic plan view showing the semiconductor device according to the disclosure. FIG. 3 is a cross-sectional view, taken along line II-II shown in FIG. 2, showing the semiconductor device according to the present disclosure. FIG. 4 is a cross-sectional view, taken along line III-III shown in FIG. 2, showing the semiconductor device according to the present disclosure. In FIGS. 3 and 4, cross-sections are not hatched.

Referring to FIGS. 1 and 2, the semiconductor device 11 includes a supporting body 13, at least one thick film metal body 17, an element structure 14, and a resin structure 24 including at least a first resin body 19. The supporting body 13 may include a semiconductor (for example a group VI semiconductor, such as silicon). The supporting body 13 has a first principal face 13b and a second principal face 13c opposite to the first principal face 13b. The supporting body 13 has an edge 13k that defines the first principal face 13b of the supporting body 13.

The resin structure 24 is disposed on the supporting body 13, while the resin structure 24 does not cover the side face 13s at the edge 13k of the supporting body 13. The resin structure 24 includes a first resin body 19 that covers at least the side face of the thick film metal body 17, which is disposed on the first principal face 13b of the supporting body 13.

Referring to FIG. 1, the resin structure 24 may include a second resin body 25 in addition to the first resin body 19, and however, the resin structure 24 of the semiconductor device 11 is not limited thereto.

The resin structure 24 can have at least one of structure 1 and structure 2 below. In structure 1, the resin structure 24 further includes the second resin body 25, which is located on the second principal face 13c of the supporting body 13.

In structure 2: the first resin body 19 of the resin structure 24 is provided with a first region 19b and a second region 19c on the first principal face 13b, and the second region 19c is greater than the first region 19b in thickness on the supporting body 13.

In the semiconductor device 11 in which the supporting body 13 mounts the first resin body 19 and the thick film metal body 17 on the first principal face 13b thereof, disposing the second resin body 25 on the second principal face 13c of the supporting body 13 can reduce the warpage of the supporting body 13 of the semiconductor device 11. This structure allows the supporting body 13 to be disposed between the first and second resin bodies 19 and 25. Further, providing the first resin body 19 with the first and second regions 19c and 19b on the first principal face 13b of the supporting body 13 allows the separation of the first resin body 19 into a thinner portion, e.g., the first region 19b, and a thicker portion, e.g., the second regions 19c, to facilitate stress relaxation.

Specifically, the semiconductor device 11 can have several forms.

### The First Form

The exemplary semiconductor device 11 is provided with the resin structure 24 that includes the first and second resin bodies 19 and 25. The first and second resin bodies 19 and 25 do not cover the side face 13s of the supporting body 13 at the edge 13k to be separated away from each other. The semiconductor device 11 allows the first and second resin bodies 19 and 25 to be disposed on the opposite sides of the supporting body 13, so that the resin bodies (19 and 25) are located the first and second principal faces 13b and 13c, respectively, to apply respective stresses to the supporting body 13. These stresses work on the opposite faces from the resin bodies (19 and 25), so that at least a portion of the stresses cancels out in the supporting body 13. The first resin body 19 further includes the first and second regions 19b and 19c, and the arrangement of the thinner first region 19b and the thicker second region 19c of the first resin body 19 acts to disperse the stress.

### The Second Form

The exemplary semiconductor device 11 is provided with the resin structure 24 that includes the first and second resin bodies 19 and 25. The first and second resin bodies 19 and 25 do not cover the side face 13s of the supporting body 13 at the edge 13k to be separated away from each other. However, the first resin body 19 does not have the combination of the first and second regions 19b and 19c. Specifically, the first region 19b can be removed from the semiconductor device 11 shown in FIGS. 1 to 4. The semiconductor device 11 allows the first and second resin bodies 19 and 25 to be disposed on the opposite sides of the supporting body 13, so that the resin bodies (19 and 25) are located the first and second principal faces 13b and 13c, respectively, to apply respective stresses to the supporting body 13. These stresses work on the opposite faces from the resin bodies (19 and 25), so that at least a portion of the stresses cancels out in the supporting body 13.

### The Third Form:

The exemplary semiconductor device 11 is provided with the resin structure 24 that includes the first resin body 19 but does not include the second resin body 25. Specifically, the second resin body 25 is removed from the semiconductor device 11 shown in FIGS. 1 to 4, and the first resin body 19 alone is located on the supporting body 13. Further, the first resin body 19 is provided with the first and second regions 19b and 19c. The semiconductor device 11 allows the arrangement of the thinner first region 19b and the thicker second region 19c of the first resin body 19 to act to disperse the stress therein, thereby lowering the resultant stress.

In the semiconductor device 11 according to the first and third forms, the difference in resin thickness between the first and second regions 19b and 19c prevents the first resin body 19, as a mass of resin, from applying stress to the supporting body 13. Further, the first and second regions 19b and 19c of the different thicknesses reduce the volume of the first resin body 19. Forming the level of difference in resin thickness between the first and second regions 19b and 19c can be carried out, for example, by half-cutting with a dicing saw or resin-molding using a mold.

The CSP structure mounts the resin structure 24 on the semiconductor chip. Specifically, the first resin body 19 can be disposed on the semiconductor chip, in particular, on the front face of the semiconductor chip. Further, the second resin body 25 can be disposed on the semiconductor chip, in particular, on the back face of the semiconductor chip. The second resin body 25 may have a thickness smaller than that of the first resin body 19. The first and second resin bodies 19 and 25 may be disposed on the first and second areas of the semiconductor chip, respectively, and the second area that mounts the second resin body 25 can be made smaller than the first area that mounts the first resin body 19 mounts. The first resin body 19 works to potentially cause the wafer product to be warped, while the second resin body 25 alleviates the potential warpage of the wafer product. Accordingly, the volume of the second resin body 25 may be made comparable to that of the first resin body 19.

Referring to FIGS. 1 and 2, the first region 19b of the semiconductor device 11 is provided along exemplary four portion of the edge 13k. However, the first region 19b can be provided partially on the edge 13k, for example, can be provided along at least part of the exemplary four portion of the edge 13k or along a part of the edge 13k of the supporting body 13. The second region 19c can adjoin the first region 19b.

In the semiconductor device 11, providing the first region 19b partially on the edge 13k of the supporting body 13 makes the thickness of the first resin body 19 (for example, epoxy resin) small at that part of the edge 13k contiguous to the first region 19b, which extends from the inner area to the scribe area of the semiconductor device 11. In the fabricating processes, the thick second regions 19c in respective adjoining sections of the wafer (which correspond to semiconductor chips, each including the supporting body 13) are separated by the thin first region 19b, which is disposed across the adjoining sections, on the wafer to relieve the stress, and in the state of the relieved stress, the adjoining sections are divided into semiconductor chips. This leads to the relaxation of stress in the semiconductor device 11 of the chip size package (CSP) structure.

As shown in FIGS. 1 and 2, the exemplary semiconductor device 11 provides the supporting body 13 with a first edge 13k1, a second edge 13k2, a third edge 13k3, and a fourth edge 13k4. The first and second edges 13kl and 13k2 extend in the first direction (the X-axis of the coordinate system CS), and the third and fourth edges 13k3 and 13k4 extend in the second direction (the Y axis of the coordinate system CS). The exemplary first principal face 13b is defined by the multiple edges, such as first to fourth edges 13kl to 13k4.

The exemplary semiconductor device 11 may provide the first resin body 19 with the first region 19b that extends along all of the first to fourth edges 13kl to 13k4. Specifically, the first region 19b has an annularly-closed shape to surround the second region 19c along the edge 13k of the supporting body 13. In the semiconductor device 11 in which the first region 19b is provided with the annularly-closed shape, the first region 19b encircling the second region 19c allows the stress within the second region 19c to decrease outward, specifically, toward the edge 13k.

The first region 19b may be disposed along any one of the first to fourth edges 13kl to 13k4. Further, the first region 19b may be disposed along at least two edges of the first to fourth edges 13kl to 13k4 (for example, two adjacent edges or two edges of the first to fourth edges 13kl to 13k4 apart from each other). Furthermore, the first region 19b can be disposed on at least three of the first to fourth edges 13kl to 13k4.

Referring to FIGS. 3 and 4, the exemplary semiconductor device 11 has a CSP structure. Specifically, the exemplary semiconductor device 11 is provided with the supporting body 13, the at least one thin film metal electrode 15, the at least one thick film metal body 17, and the resin structure 24, and further, an insulating layer 21.

The thin film metal electrode 15 is provided on the first principal face 13b of the supporting body 13. The thick film metal body 17 is located on the thin film metal electrode 15 and may include, for example, a metal film. The thick film metal body 17 has a thickness greater than that of the thin film metal electrode 15. The resin structure 24 includes at least one of the first and second resin bodies 19 and 25. The second resin body 25 is disposed on the second principal face 13c of the supporting body 13, and the exemplary second resin body 25 may be provided over the entire second principal face 13c.

The semiconductor device 11 can have one or more semiconductor elements 31 (for example, active elements, such as transistors) in the supporting body 13. Further, the semiconductor device 11 can include an insulating structure 33, which is provided between the thin film metal electrode 15 and the semiconductor elements 31. At least one of the semiconductor element 31 can be electrically connected to at least one thick film metal body 17 via an opening of the insulating structure 33. The insulating structure 33 may include, for example, one or more insulating films, and these insulating films can include a silicon-based inorganic insulating film or a resin film.

In the supporting body 13, the first principal face 13b has an element area 13d and a peripheral area 13c. The element area 13d mounts the semiconductor elements 31, and also mounts the first resin body 19, the thin film metal electrode 15, and the thick film metal body 17. The peripheral area 13e may mount the first resin body 19, and the metal electrode 15 and the thick film metal body 17 are apart from the peripheral area 13c. The peripheral area 13e has an annularly-closed shape to encircle the element area 13d.

The thin film metal electrode 15 is disposed on the first principal face 13b of the supporting body 13, and specifically, may be electrically connected to at least one semiconductor element 31. The thin film metal electrode 15 may include aluminum, for example.

The thick film metal body 17 is located on the thin film metal electrode 15 and the insulating layer 21. The thick film metal body 17 may include a metal film, which comprises copper. The thick film metal body 17 can include, for example, a copper plating film and a seed layer for plating.

The first region 19b of the first resin body 19 has a thickness smaller than that of the thick film metal body 17. The first resin body 19 reaches the edge 13k of the supporting body 13 and is contiguous thereto. Further, the second resin body 25 may be configured to reach the edge 13k of the supporting body 13 and is contiguous thereto.

The first resin body 19 is disposed on the first principal face 13b of the supporting body 13, and covers the side face 17b of the thick film metal body 17. The first resin body 19 may include epoxy resin, and the second resin body 25 may include epoxy resin.

The insulating layer 21 has one or more first openings 22b and 22c, and each of the first openings (22b and 22c) is located on the thin film metal electrode 15.

For example, the insulating layer 21 can cover the edge 16b of the thin film metal electrode 15 and prevent the thick film metal body 17 from reaching the underlying structure, such as of the thin film metal electrode 15, in the device area 13d. The insulating layer 21 may include a resin body, such as polyimide resin. The insulating layer 21 has a simply-connected region in which the total area of the openings 22b of the insulating layer 21 is larger than that of the upper face of the insulating layer 21.

The supporting body 13, the thin film metal electrode 15, and the thick film metal body 17 are arranged in the direction of the first axis Ax1. The upper face 17c of the thick film metal body 17 and the upper face 19d of the first resin body 19 can extend along the reference plane REF that intersects the first axis Ax1, and accordingly, there is substantially no difference in level between the upper face 19d of the resin body 19 and the upper face 17c of the thick film metal body 17.

The second inorganic insulating film 23 may be disposed on at least a portion of the first principal face 13b of the supporting body 13, and the second inorganic insulating film 23 may be disposed between the first resin body 19 and the insulating layer 21. The second inorganic insulating film 23 includes a simply-connected region in which the total area of the second openings 23b of the second inorganic insulating film 23 is larger than that of the upper face of the second inorganic insulating film 23. For example, the second inorganic insulating film 23 extends from the element area 13d outward beyond the boundary between the peripheral area 13e and the element area 13d, and can reach the edge of the first principal face 13b of the supporting body 13 and is contiguous thereto.

The second inorganic insulating film 23 can include a silicon-based inorganic oxide film and/or a silicon-based inorganic oxynitride film, which can be deposited at a film-forming temperature that does not exceed the heat-resistant temperature of the underlying structure, and may include an inorganic film containing silicon and nitrogen elements, such as SiN.

The resin structure 24 may include one or both of the first and second resin bodies 19 and 25. In the element area 13d, the first resin body 19 is separated away from the supporting body 13 and the insulating layer 21 by the second inorganic insulating film 23.

The second resin body 25 of the resin structure 24 can be disposed on at least a portion of the second principal face 13c of the supporting body 13. The exemplary second resin body 25 extends from the element area 13d outward beyond the boundary between the element area 13d and the peripheral area 13e on the second principal face 13c, and can reach the outer edge of the second principal face 13c of the supporting body 13 and contiguous thereto.

The exemplary second resin body 25 extends along the second principal face 13c from the outer edge of the second principal face 13c or neighborhood of the outer edge, for example, a position away from the outer edge, toward the center of the second principal face 13c. The semiconductor device 11 allows the second resin body 25, which extends along the second principal face 13c of the supporting body 13, to maintain the coplanarity of the supporting body 13.

The second resin body 25 extends along the second principal face 13c of the supporting body 13. The second resin body 25 may be disposed, for example, over the entire second principal face 13c, and however, the present disclosure is not limited thereto. The second resin body 25 may be provided on the major part of the second principal face 13c.

As shown in FIG. 3, the thickness D17 of the thick film metal body 17 is greater than the thickness D15 of the thin film metal electrode 15, and as shown in FIG. 4, the thickness D19 of the first resin body 19 is greater than the thickness D21 of the insulator layer 21.

In the semiconductor device 11 which makes the thickness D17 of the thick film metal body 17 greater than the thickness D15 of the thin film metal electrode 15 and makes the thickness D19 of the first resin body greater than the thickness D21 of the insulating layer 21, the top face 17c of the thick film metal body 17 and the top face 19d of the first resin body 19 both extend along the reference plane REF to provide a structure of a chip size package (for example, a CSP structure). This structure allows the resin structure 24, which includes the first resin body 19 having the first and second regions 19b and 19c, to reduce the warpage of the supporting body 13 that may be caused by stress from the thick film metal body 17 and the first resin body 19. Further, the resin structure 24, which includes the first and second resin bodies 19 and 25, can reduce the warpage of the supporting body 13 that may be caused by stress from the thick film metal body 17 and the first resin body 19.

In the resin structure 24, specifically, the second inorganic insulating film 23 has one or more second openings 23b on the thin film metal electrode 15, and the second openings 23b are located in the first openings 22b and 22c of the insulating layer 21. The thick film metal body 17 is connected to the thin film metal electrode 15 through the second opening 23b of the second inorganic insulating film 23. The exemplary thick film metal body 17 is located on the thin film metal electrode 15 and the insulating layer 21. The second inorganic insulating film 23, which is disposed between the supporting body 13 and the first resin body 19, extends from the edge of the second opening 23b of the second inorganic insulating film 23 toward the edge 13k of the supporting body 13.

In the semiconductor device 11, the second inorganic insulating film 23 extends along the supporting body 13 from the edge of the second opening 23b of the second inorganic insulating film 23 outward toward the outer edge 13h of the supporting body 13 to encircle the thick film metal body 17 at the bottom thereof.

Referring to FIGS. 1 and 2, the first resin body 19 and the exemplary four metal bodies of the thick film metal bodies 17 are arranged such that the first resin body 19 is provided between the exemplary four metal bodies of the thick film metal bodies 17 to form a CSP structure. In the exemplary semiconductor device 11, each of the exemplary four metal bodies of the thick film metal bodies 17 is connected to the underlying thin film metal electrode 15 via a single first opening 22b and a single second opening 23b. In the exemplary semiconductor device 11, the stress that the thick film metal body 17 potentially applies to the supporting body 13 relates not only to the area of the top face 17c of the thick film metal body 17 but also to the volume of the thick film metal body 17. The proportion of the thick film metal body 17 on the entire principal face of the supporting body 13 (hereinafter referred to as “filling rate”) can be defined, for example, in a wafer product during a wafer process or in a semiconductor chip fabricated thereby.

According to some estimates of prior semiconductor chips, the prior semiconductor chips may have a fill factor of 20 to 30 percent. However, higher fill rates are likely to be estimated in wafer products during wafer processing and in semiconductor chips obtained from finished wafer products.

Referring to FIGS. 3 and 4, the thin film metal electrode 15 may include one or more pad electrodes. The thick film metal bodies 17 may include one or more metal columns connected to the respective pad electrodes of the thin film metal electrodes 15. The first principal face 13b of the supporting body 13 includes a first region 13f and a second region 13g, and the first region 13f mounts the metal columns of the thick film metal bodies 17, while the second region 13g mounts the thick resin body. For example, the area of the first region 13f is larger than that of the second region 13g.

The semiconductor device 11 makes the area of the first region 13f larger than that of the second region 13g to form a structure in which the supporting body 13 receives stress from the thick film metal body 17 in the first region 13f. In this structure, the first resin body 19 is disposed on the second region 13g of the supporting body 13 to cover the side face 17b of the thick film metal body 17. The above structure causes the supporting body 13 to receive stress from the first resin body 19 in the second area 13g.

Further, as shown in FIG. 4, the second principal face 13c has a third area 13i and a fourth area 13j. The third and fourth areas 13i and 13j are defined to be associated with the first and second areas 13f and 13g of the first principal face 13b, respectively.

The second resin body 25 can be disposed on at least the third area 13i to support the supporting body 13 against the thick film metal body 17. The second resin body 25 can extend outward beyond the boundary between the third and fourth areas 13i and 13j (onto the fourth area 13j) to support the supporting body 13 against the thick film metal body 17 and the second resin body 25. The second resin body 25 may be separated away from the edge 13k of the supporting body 13.

Referring to FIGS. 3 and 4, the thin film metal electrode 15 is disposed just under the thick film metal body 17. The first openings 22b and 22c of the insulating layer 21 each are located on the thin film metal electrode 15. The thick film metal body 17 covers the entire top face of the thin film metal electrode 15 in each of the first openings 22b and 22c of the insulating layer 21 and extends therefrom beyond the edge of the insulating layer 21 onto the top face of the insulating layer 21.

The area of the top face of the thin film metal electrode 15 (size W15) is greater than that of the insulating layer 21 (size W21).

The semiconductor device 11 allows the thick film metal body 17 to make contact with the thin film metal electrode 15 via each of the first openings 22b and 22c of the insulating layer 21 on the first principal face 13b of the supporting body 13. Providing the insulating layer 21 on the first principal face 13b can avoid unwanted contact between the thin film metal electrode 15 and the thick film metal body 17, and form its flattened face on the first principal face 13b of the supporting body 13. This flattened face serves as a base to form the second inorganic insulating film 23 on to reduce a potential increase in thermal stress from the bending or level of difference of a base to form the first resin body 19 and/or the thick film metal body 17 on.

The thick film metal body 17 covers the entire top face of the thin film metal electrode 15 at each of the first openings 22b and 22c of the insulating layer 21. Further, the insulating layer 21 may be a simply-connected region in which the total area of the first openings 22b and 22c of the insulating layer 21 is greater than that of the upper surface of the insulating layer 21.

In the semiconductor device 11, the insulating layer 21 on the first principal face 13b as above can make the total area of the first openings 22b and 22c greater than that of the upper surface thereof to prevent unwanted contact between the thick film metal body 17 and the thin film metal electrode 15. Making the insulating layer 21 simply-connected allows the insulating layer 21 to cover more areas of the upper surface of the first principal face 13b and to form a flattened base to form the second inorganic insulating film 23 on.

Further, the first resin body 19 is also disposed on the first principal face 13b of the supporting body 13 to prevent unwanted contact between the thick film metal body 17 and the thin film metal electrode 15. The first resin body 19 may be also made simply-connected to allow the total area of the openings of the first resin body 19 to be larger than that of the top face of the first resin body 19.

Referring to FIG. 3, the insulating layer 21 has an inner edge 22f that defines each of the first openings 22b and 22c of the insulating layer 21, and an outer edge 22g that defines the size of the insulating layer 21. The outer edge 22g of the insulating layer 21 may be apart from the edge 13k of the supporting body 13, while the first resin body 19 reaches and is contiguous to the edge 13k of the supporting body 13. Accordingly, the semiconductor device 11 allows the insulating layer 21 to reach the vicinity of the edge 13k of the supporting body 13 or, for example, to be contiguous to the boundary of the scribe region of the supporting body 13.

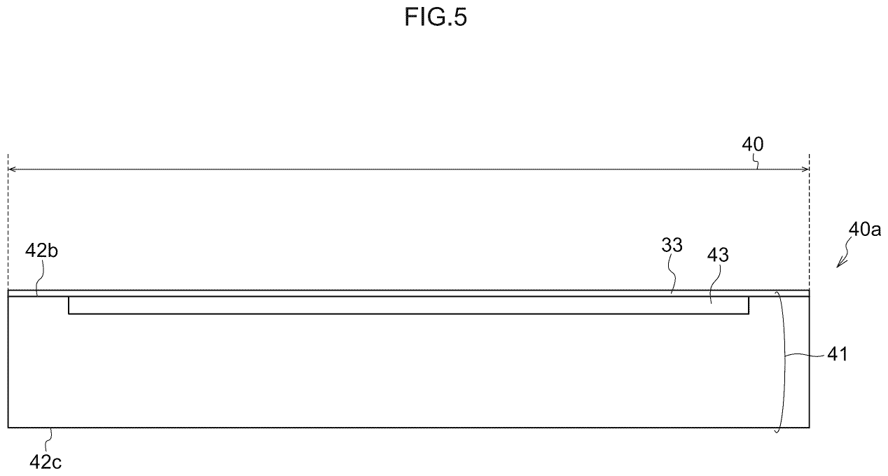

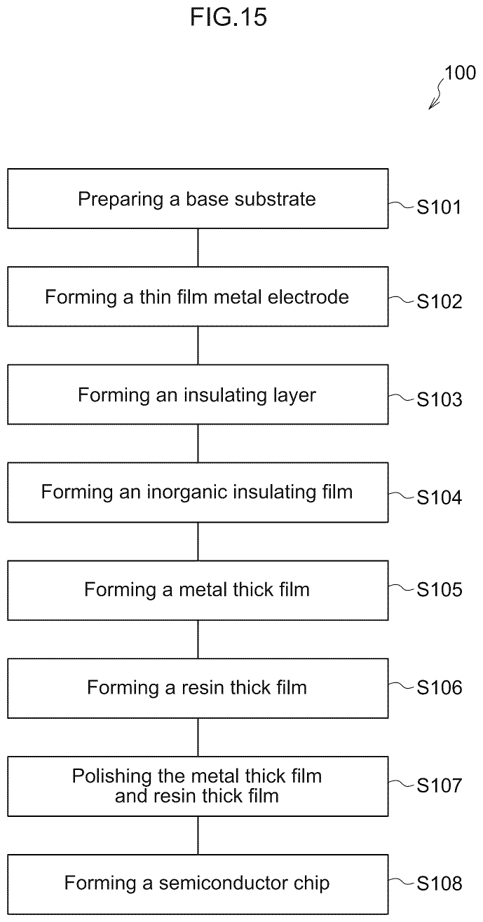

FIGS. 5 to 14 each are a cross-sectional view showing a major process in the method for fabricating the semiconductor device according to the present disclosure. Each of FIGS. 5 to 14 shows the progress of the wafer product in the fabrication process, taken along the cross-section corresponding to line III-III shown in FIG. 3. The cross sections of FIGS. 5 to 14 are not hatched for simplicity. FIG. 15 is a process flow showing major steps in the method for fabricating the semiconductor device. In the following description, for the sake of better understanding, identical or similar parts will be demoted by the reference numerals already used in the above description, where possible.

In the first step shown in FIG. 5 (referred to as, for example, S101 in FIG. 15), a base substrate 41 is prepared which is formed, for example, by processing a semiconductor wafer. The base substrate 41 may include a semiconductor, such as silicon. The semiconductor region of the base substrate 41 has a first principal face 42b and a second principal face 42c opposite to the first principal face 42b. The base substrate 41 includes multiple sections (referred to as 40 in FIG. 5) arranged on the first principal face 42b (to form, e.g., a one-dimensional or two-dimensional array of the sections). Each section 40 includes one or more semiconductor elements 43. FIGS. 5 to 14 each depict one of the multiple sections. The semiconductor elements 43 are formed in the semiconductor region. The semiconductor elements 43 may include an electron element, such as transistors, electrodes, and interconnects, which can be fabricated by applying the following semiconductor processes to a semiconductor substrate, such as a wafer.

In the second step, an insulating structure 33 covers the base substrate 41 to form a wafer product 40a. The insulating structure 33 can include at least one of inorganic and organic insulators, and specifically, the insulating structure 33 covers the region of the semiconductor elements 43.

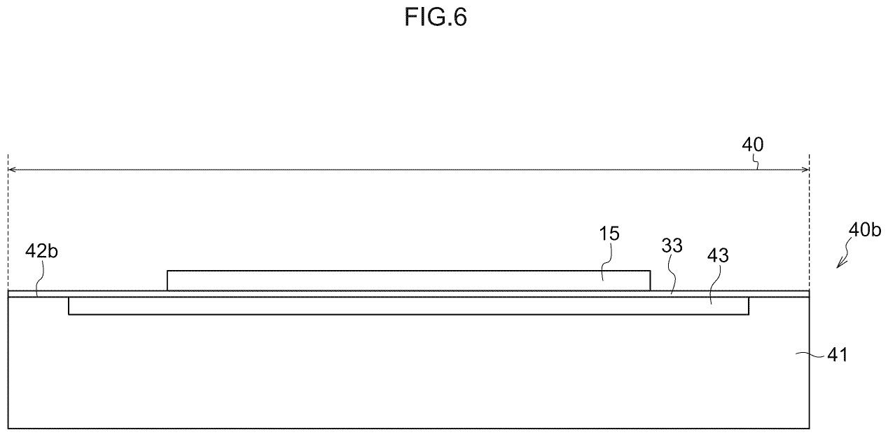

In the third step shown in FIG. 6 (referred to as, e.g., S102 in FIG. 15), a thin film metal electrode 15 is formed in each of the sections 40 to obtain a wafer product 40b. The thin film metal electrode 15 is deposited on the first principal face 42b of the base substrate 41, in particular, on the insulating structure 33, and can be connected to the semiconductor elements 43 through the opening(s) of the insulating structure 33 in the section 40. Forming the thin film metal electrode 15 may use semiconductor processes, such as metal layer deposition, photolithography, and etching. The thin film metal electrode 15 can be made of, for example, aluminum.

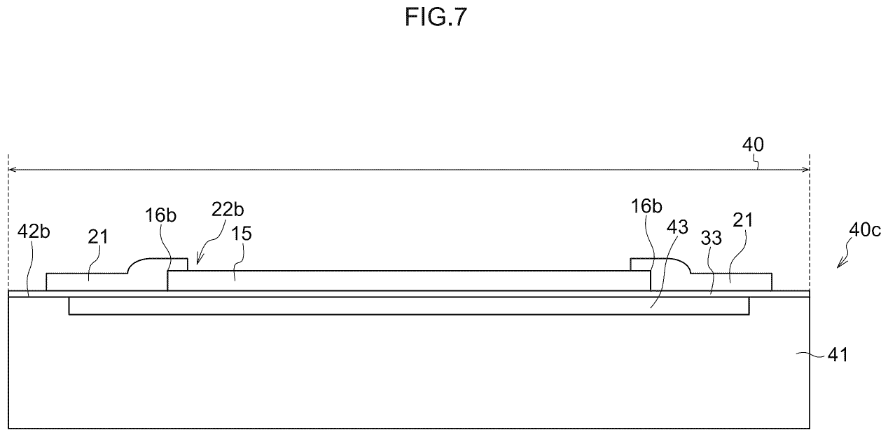

In the fourth step shown in FIG. 7 (referred to as, e.g., S103 in FIG. 15), the insulating layer 21 is formed on the first principal face 42b in each of the sections 40 to obtain a wafer product 40c. The insulating layer 21 has a first opening 22b on the thin film metal electrode 15, and covers the edge 16b of the thin film metal electrode 15. Forming the insulating layer 21 may use semiconductor processes, such as coating an organic substance, baking, photolithography, and etching. The insulating layer 21 can includes, for example, polyimide resin.

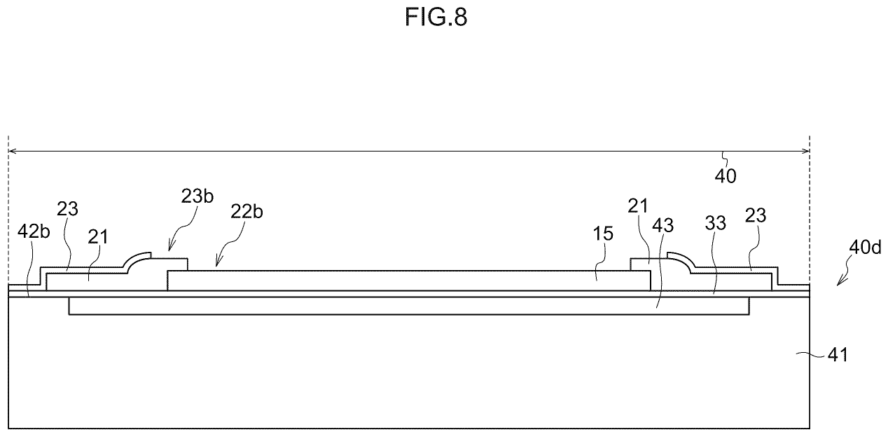

In the fifth step shown in FIG. 8 (referred to as, i.e., S104 in FIG. 15), the resin structure 24 is formed on the first principal face 42b of the base substrate 41, and in this process, a second inorganic insulating film 23 is formed to obtain a wafer product 40d. The second inorganic insulating film 23 is deposited on the insulating layer 21. The second inorganic insulating film 23 has a second opening 23b, which is aligned with the first opening 22b, on the thin film metal electrode 15. For example, the size of the second opening 23b may be larger than that of the first opening 22b. The second inorganic insulating film 23 may include silicon-based inorganic nitride, such as SiN.

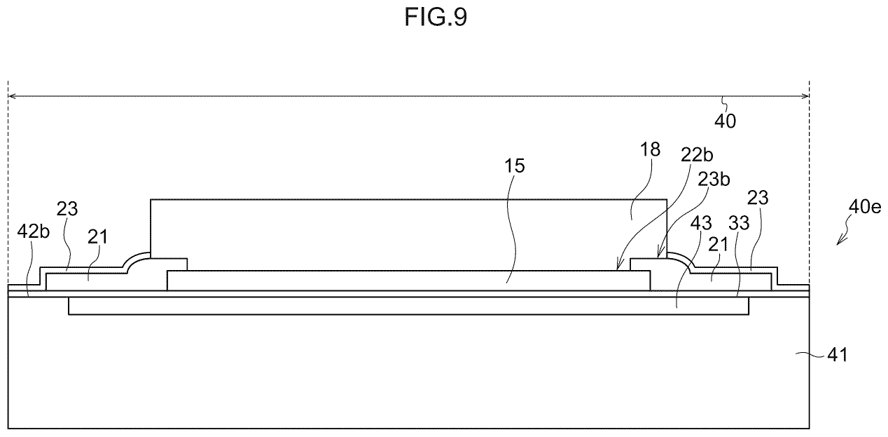

In the sixth step shown in FIG. 9 (referred to as, e.g., S105 in FIG. 15), the metal thick film 18 is formed on the first principal face 42b in each of the sections 40 to obtain a wafer product 40c. The thick metal film 18 may include copper. The metal thick film 18 is located on the thin film metal electrode 15 to be connected to the thin film metal electrode 15 through the first opening 22b of the insulating layer 21. The thick metal film 18 has a thickness greater than that of the thick film metal body 17. The metal thick film 18 is formed by, for example, a plating process, and specifically, semiconductor processes, such as, the deposition of a seed layer (pattern formation.

Note that, specifically, forming the resin for the second resin body 25 will be explained below as another exemplary of the resin structure 24.

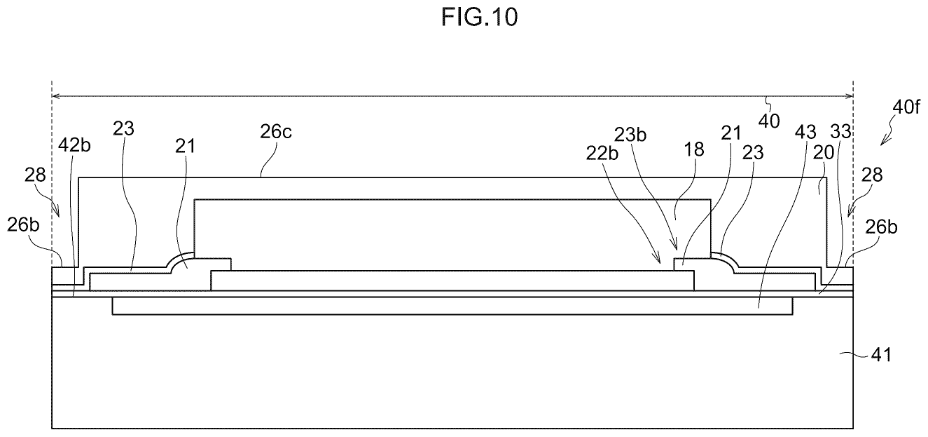

In the seventh step shown in FIG. 10 (referred to as, e.g., S106 in FIG. 15), at least one thick resin film 20 is formed on the wafer product 40e to obtain a wafer product 40f. The exemplary thick resin film 20 is formed on the first principal face 42b to cover the top and side faces of the metal thick film 18 in the section 40. The thick resin film 20 has a thickness greater than that of the first resin body 19. Further, the thick resin film 20 has a thickness greater than that of the metal thick film 18.

Forming the resin structure 24, which includes the thick resin film 20, on the base substrate 41 includes heat-treating the resin.

As shown in FIG. 10, the thick resin film 20 as an example of the resin structure 24 may be formed by, for example, coating, specifically, semiconductor processes, such as coating, baking, and dicing with a dicing saw. The thick resin film 20 can include, for example, epoxy resin, and however, the formation of the thick resin film 20 is not limited thereto. The thick resin film 20 can be formed, for example, by resin molding using a mold.

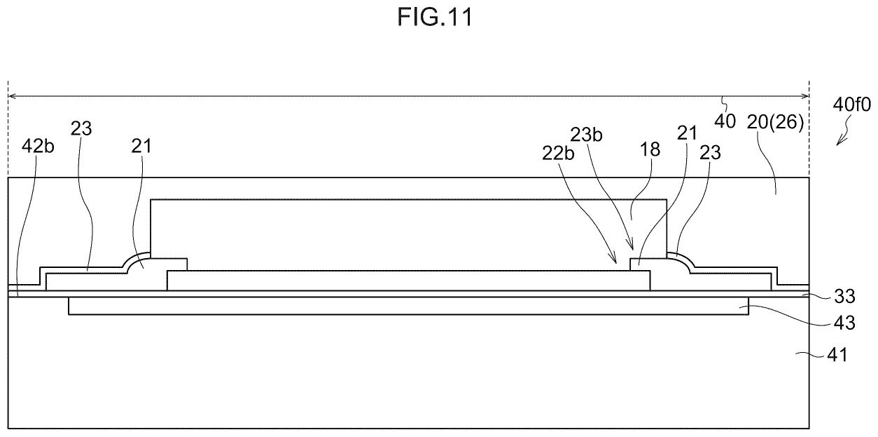

As shown in FIG. 11, resin is applied onto the wafer product 40e (see FIG. 9) to obtain a wafer product 40f0. The wafer product 40f0 has a first resin thick film 26, which is formed on the first principal face 42b in the section 40. The first resin thick film 26 may be formed on the metal thick film 18 of a thickness approximately the same as that of the metal thick film 18. The first resin thick film 26 has a side portion located to cover the side face of the metal thick film 18 and may be formed to have a thickness approximately twice that of the metal thick film 18 at that side portion of the first resin thick film 26.

If the surface of the wafer product 40f0 is not processed, the first resin thick film 26 of FIG. 11 is referred to as the thick resin film 20 as it is.

Alternatively, the surface of the wafer product 40f0 may be processed. Specifically, as shown in FIG. 10, the top face of the first thick resin film 26 of the wafer product 40f0 is processed to produce the thick resin film 20 therefrom. The thick resin film 20 has a structure 28, for example, at least one of a recess and a groove, on its surface. The exemplary recess and groove of the structure 28 can be formed with a dicing saw.

Specifically, the exemplary structure 28 can be formed by half-cutting the first resin thick film 26 using a dicing saw. The first resin thick film 26 may be half-cut along the boundary between adjoining sections 40 that mounts the first resin thick film 26 thereon. Further, the first resin thick film 26 may be half-cut along at least one of the multiple boundaries of the sections 40. Furthermore, half-cutting the first resin thick film 26 can be performed at each of the boundaries of the sections 40. The depth of the recess, which is formed using a dicing saw, does not reach the wafer product 40e. An exemplary depth may be about half of the thickness of the resin formed on the front face of the wafer product 40c. The depth of half-cutting can be determined depending on the reduction of the amount of warpage.

The thick resin film 20 has a thin first region 26b that includes the structure 28 in the first thick resin film 26, and a second region 26c that has a larger thickness than that of the first region 26b. The structure 28 provides the semiconductor device 11 with the first region 19b, and the second region 19c is adjacent to first region 19b. The shape of the surface, such as recesses and grooves, is made of the thin and thick parts of resin, and the thin resin parts are formed by half-cutting, while the thick resin parts are not half-cut. The structure 28 is thus formed in the first resin thick film 26, and this first resin thick film 26 may be heat treated to form the thick resin film 20.

The exemplary wafer product 40f may be provided with at least one thick resin film 20, which is formed on the base substrate 41 by forming the structure 28 in the first resin thick film 26. This can reduce the warpage of the exemplary wafer product 40f.

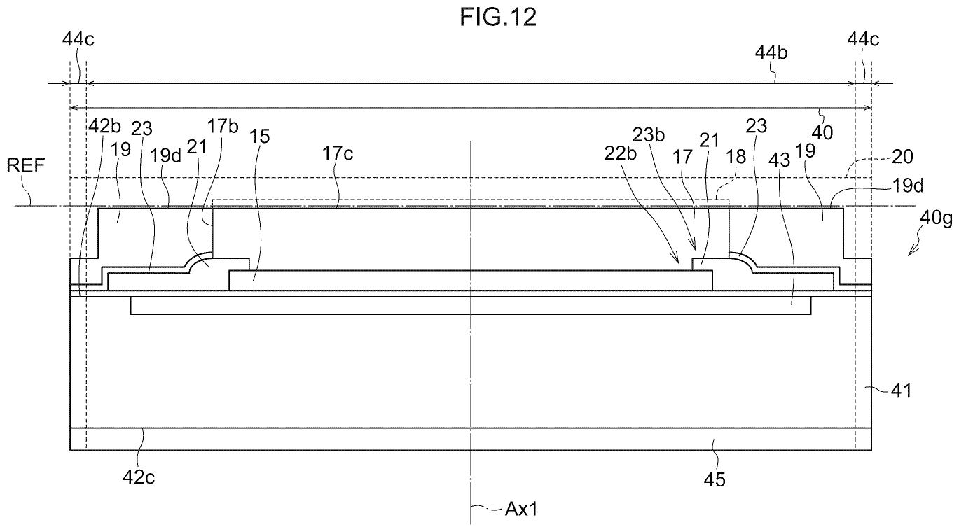

In the eighth process shown in FIG. 12 (referred to as, for example, S107 in FIG. 15), in order to obtain a wafer product 40g, the thick resin film 20 and the metal thick film 18 are ground and/or polished to produce the first resin body 19 and the metal thick film 18 therefrom, respectively. Prior to the grinding and/or polished, the wafer product 40f is fixed to a supporting plate 45. Specifically, the supporting plate 45 is attached to the second principal face 42c and separated from the wafer product 40g after the grinding and/or polished, so that the wafer product 40f has a reduced warpage, which makes it easy to secure the wafer product to the supporting plate 45 (see FIG. 12). Further, the wafer product thus ground exhibits an excellent in-plane uniformity.

In the wafer product 40g, in each of the sections 40, the side face 17b of the thick film metal body 17 is covered with the first resin body 19, and the thick film metal body 17 is located in the opening of the first resin body 19.

The base substrate 41, the thin film metal electrode 15, and the thick film metal body 17 are arranged in the direction of the first axis Ax1. The upper face 17c of the thick film metal body 17 and the upper face 19d of the first resin body 19 can extend along the reference plane REF, which intersects the first axis Ax1, to make substantially no difference in level between the upper face 19d of the resin body 19 and the upper face 17c of the thick film metal body 17.

In this fabricating method, the thick film metal body 17 has a thickness greater than that of the thin film metal electrode 15, and the first resin body 19 has a thickness greater than that of the insulating layer 21. The semiconductor device 11 is provided with the upper face 17c of the thick film metal body 17 and the upper face 19d of the first resin body 19, both of which extend along the reference plane REF to have a structure of a chip size package. This structure allows the resin structure 24 to reduce the warpage of the base substrate 41, which is produced by stress from the thick film metal body 17 and the first resin body 19 in each section 40.

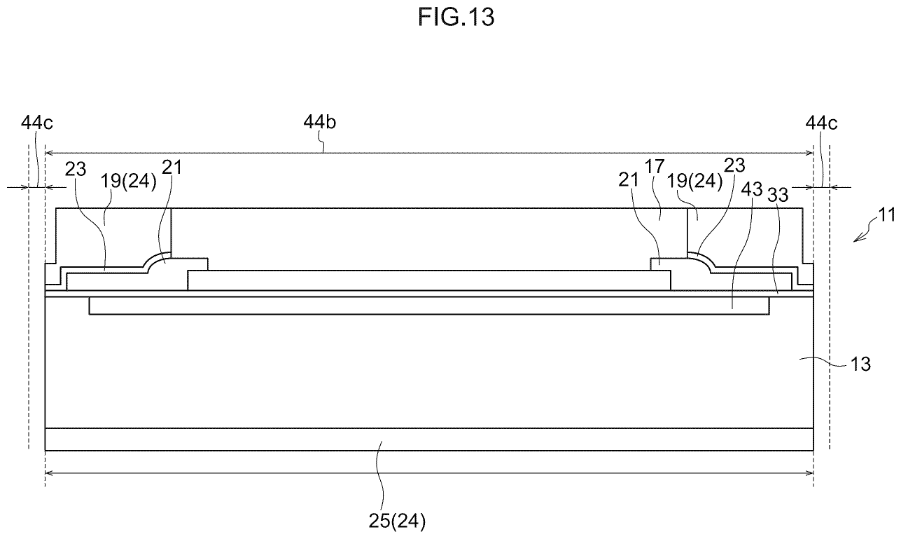

In the ninth process shown in FIG. 13 (referred to as, for example, S108 in FIG. 15), the arrayed sections 40 of the wafer product 40g are separated into the multiple semiconductor devices 11. Each of the semiconductor devices 11 has a form of a semiconductor chip.

The above fabricating method can produce the semiconductor device 11 and the wafer product 40g, the warpage of which is reduced.

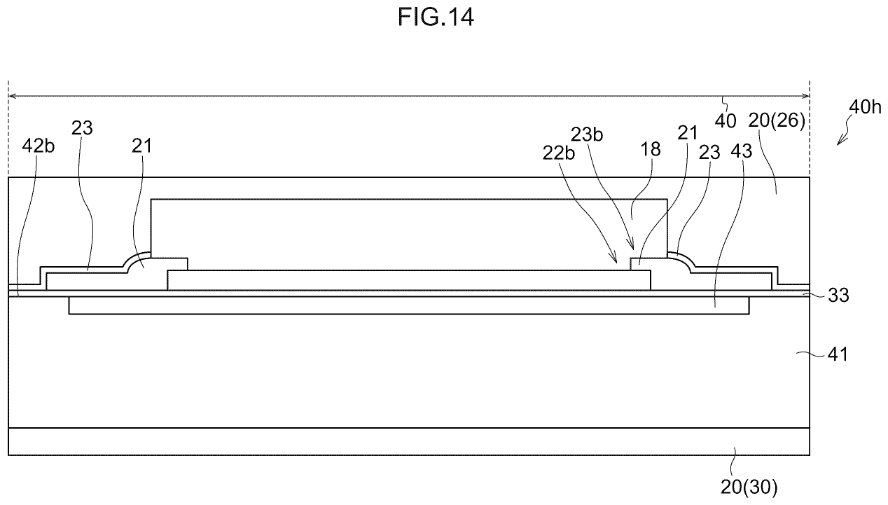

The method for fabricating the semiconductor device 11 can include the tenth process shown in FIG. 13. The tenth process is carried out to form another exemplary resin structure 24. Specifically, the second thick resin film 30 is formed on at least a portion of the second principal face 42c of one of the wafer product 40e, the wafer product 40f0, or the wafer product 40f to provide a wafer product 40h. Referring to FIG. 14, the wafer product 40h is produced from, for example, the wafer product 40f0. The second resin thick film 30 is formed as a resin film for the second resin body 25. Alternatively, the second resin thick film 30 may be formed on at least a portion of the second principal face 42c of the wafer product 40f. Alternatively, the second resin thick film 30 may be formed on at least a portion of the second principal face 42c of the wafer product 40c.

In an example, the thick resin film 20 which includes the second resin thick film 30 is formed by, for example, coating, specifically, a semiconductor process, such as coating and baking of resin. The second thick resin film 30 for the thick resin film 20 may include, for example, epoxy resin. The second thick resin film 30 thus formed can be heat-treated to form the thick resin film 20.

However, the formation of the second thick resin film 30 is not limited thereto. The second resin thick film 30 can be formed, for example, by processing of molding resin using a mold.

In an example, the exemplary thick resin film 20 may be provided with the first and second thick resin films 26 and 30, and the base substrate 41 is disposed between the first and second thick resin films 26 and 30 to reduce the warpage of the wafer product 40h, which includes the first and second resin thick films 26 and 30.

In the process in the eighth step shown in FIG. 12, the thick resin film 20 and the metal thick film 18 of the wafer product 40h can be ground to produce the first resin body 19 and the thick metal body 17 therefrom, respectively. The subsequent processing may be applied to this wafer product in the same way as the wafer product 40g.

Referring again to FIGS. 12 and 13, these drawings show that each of the sections 40 has a device area 44b and a half of a separation area 44c. The wafer product 40g (and the base substrate 41) includes two-dimensionally arrayed sections 40.

The wafer product 40g (and the base substrate 41) has a lattice-shaped arrangement (for example, two-dimensional array) of element areas 44b and a lattice-shaped separation area 44c that defines the arrangement of the element areas 44b. The separation area 44c runs between any one of the element areas 44b and another element area 44b adjacent thereto in the arrangement.

This fabricating method can reduce the warpage of the base substrate 41 without loss of the shot rate in photolithography.

The wafer product 40g includes a base substrate 41, element areas 44b in lattice-patterned sections 40, and a lattice-shaped separation area 44c running along the boundaries of these sections 40. The wafer product 40g further includes, in each section 40 or at least one section 40, at least one thin film metal electrode 15 and at least one thick film metal body 17 which are disposed on the first principal surface 42b. The wafer product 40g also includes a first resin body 19 that is disposed on the first principal face 42b across the sections 40 to fill in the space between the thick film metal bodies 17. Furthermore, the wafer product 40g further includes a resin structure 24 disposed on the base substrate 41.

The resin structure 24 has a first resin thick film 26 on the first principal face 42b of the base substrate 41. Further, the resin structure 24 may have at least one of structures 1 and 2 below.

In structure 1, the resin structure 24 further has a second thick resin film 30 on the second principal face 42c of the base substrate 41; and

In structure 2, the resin structure 24 provides the first resin thick film 26 with a thin first region 26b and a second region 26c which are on the first principal face 42b of the base substrate 41, and the second region 26c has a larger thickness than that of the first region 26b.

The resin structure 24 is formed in a process prior to the eighth process shown in FIG. 12 (referred to as, for example, S107 in FIG. 15). After forming the metal thick film 18, the first resin thick film 26 is formed. Further, forming the first and second regions 26b and 26c in the first resin thick film 26 may be performed before or after the formation of the second resin thick film 30.

The wafer product 40g is provided with the above-mentioned components, and as already described, the wafer product 40g has a large filling factor.

Referring again to FIG. 15, the method 100 of fabricating the semiconductor device 11 provides a method of making several exemplary structures. The method 100 may include the sixth step (step S106). The method 100 may further include an eighth step (step S107). The method 100 may further include a ninth step (step S108). The method 100 may further include at least one of steps S101 to S105. Subsequently, each individual step will be described. In step S101, the base substrate 41 is prepared. In step S102, the thin film metal electrode 15 is formed. In step S103, the insulating layer 21 is formed. In step S104, the second inorganic insulating film 23 is formed. In step S105, the thick metal film 18 is formed. In step S106, at least one thick resin film 20 for the resin structure 24 is formed. In step S107, the thick metal film 18 and the thick resin film 20 are ground or polished to produce the thick metal body 17 and the first resin body 19 therefrom, respectively. In step S108, the arrayed sections 40 of the wafer product 40g are separated to obtain the multiple semiconductor devices 11 (semiconductor chips and packages). The method 100 thus described completes the semiconductor device 11 and the wafer product 40g.

The present embodiments can provide the semiconductor device 11 having a CSP structure capable of reducing warpage, and the method 100 for fabricating the semiconductor device.

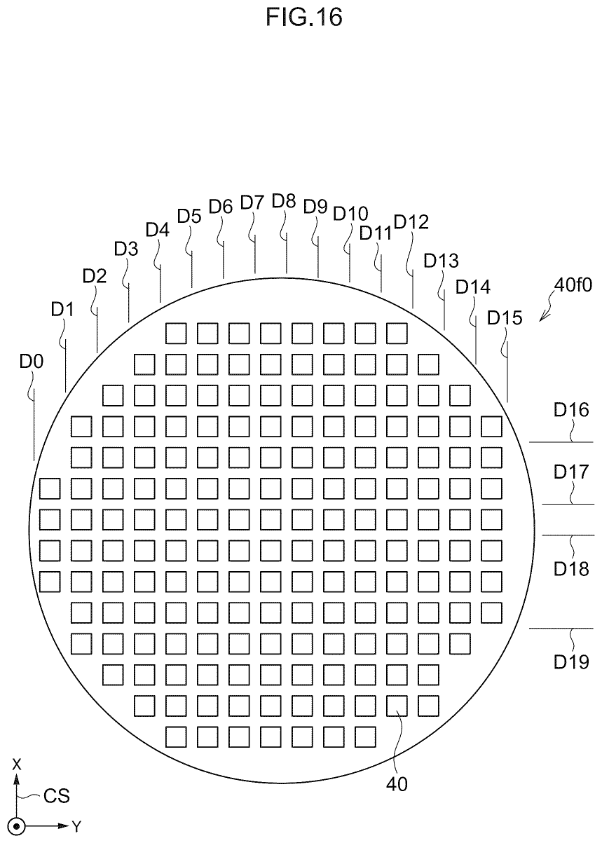

FIG. 16 is a plan view showing a wafer product and exemplary half-cut lines according to the present disclosure. The wafer product 40f0 can be half-cut in the X-axis direction of the coordinate system CS, for example, along each of the dicing lines (DO to D15), which are defined in the separation regions (for example, the scribe regions) of the sections 40. Further, the wafer product 40f0 may be half-cut along the dicing lines (D16 and D17) in the Y-axis direction of the coordinate system CS, for example, each of which is at every other separation region of the sections 40. Furthermore, the wafer product 40f0 may be half-cut along the dicing lines (D18 and D19) in the Y-axis direction of the coordinate system CS, for example, each of which is at every second separation area of the sections 40.

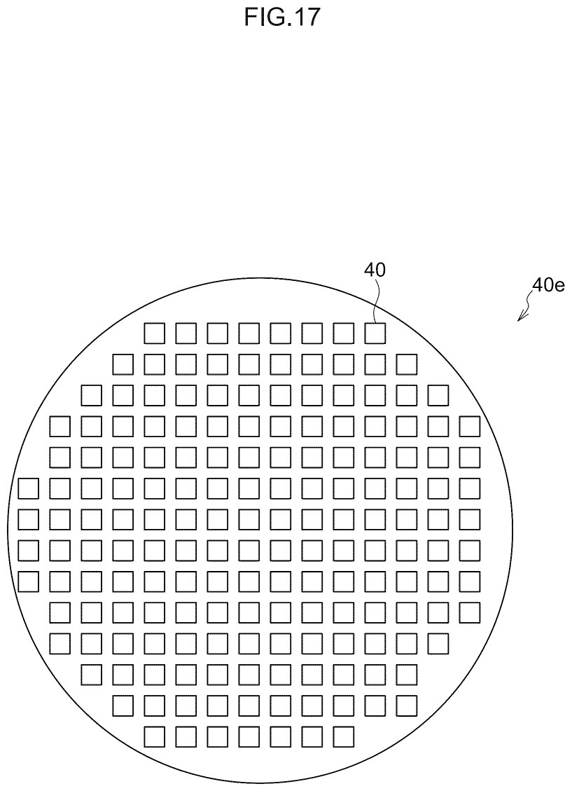

FIG. 17 is a plan view showing the wafer product according to the present disclosure. The wafer product 40e includes two-dimensionally arranged sections 40 as shown in FIG. 17.

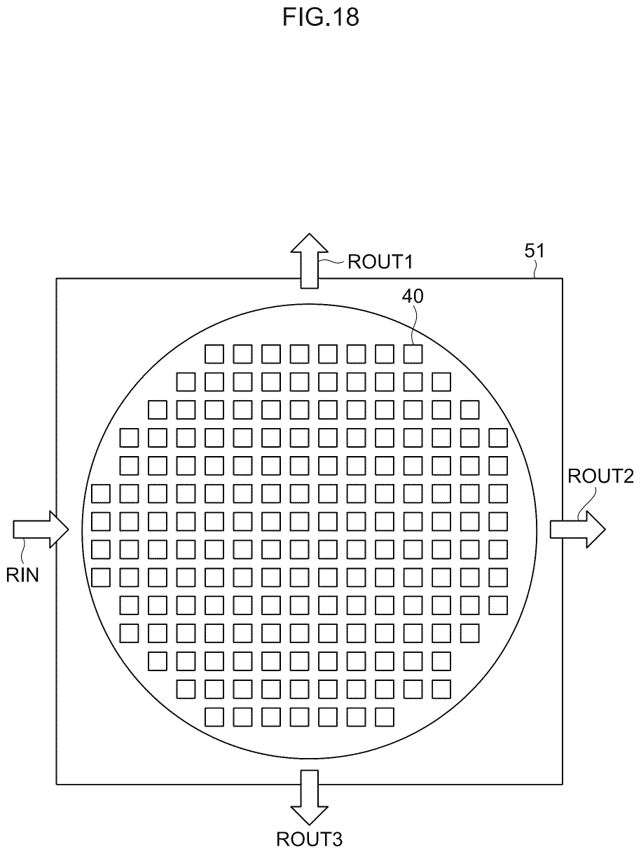

FIG. 18 is a plan view showing a wafer product and a mold according to the present disclosure. The wafer product 40e is located in a resin mold 51 prepared, as shown in FIG. 18, in forming a thick resin film in step S106 in FIG. 15.

Molding-resin is injected into the mold 51 as shown by the arrow RIN, and a surplus of the injected resin is discharged as shown by the arrows ROUT1, ROUT2, and ROUT3.

This resin-molding alone can produce a product having substantially the same size as the wafer, e.g., wafer scale product, using the mold 51. The resin structure 24 of this product may include at least one of a first resin thick film 26 and a second resin thick film 30. The first thick resin film 26 (or the second thick resin film 30), which is formed by molding, may be half-cut by dicing.

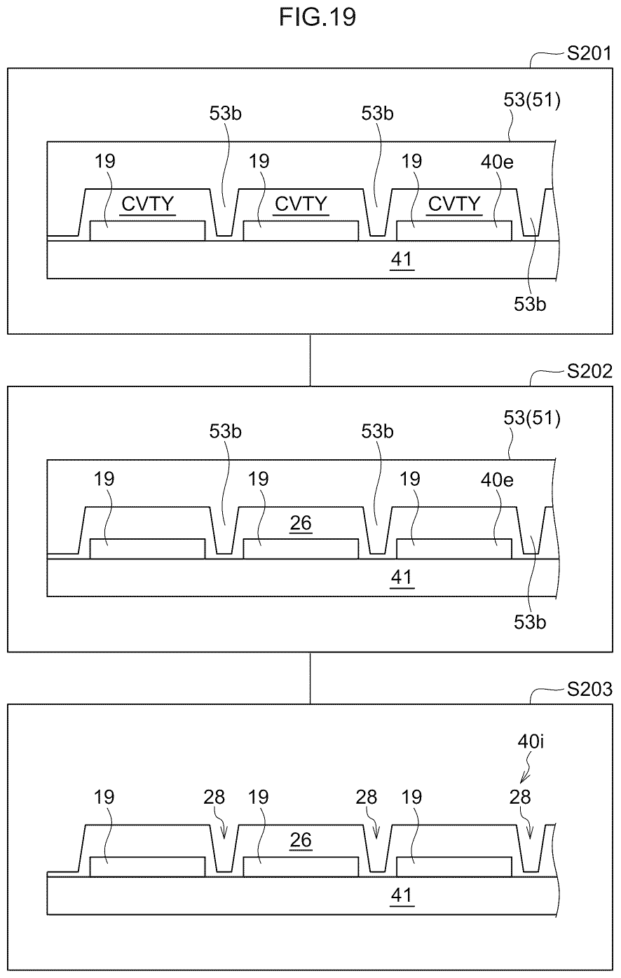

FIGS. 19, 20, and 21 are drawings showing exemplary steps in the method for fabricating the semiconductor device according to the present disclosure. The fabricating method shown in FIGS. 19, 20, and 21 uses the mold 51 (respective molds 53, 55, and 57). The mold 51 (53, 55, and 57) has at least one cavity CVTY. The mold 51 (53, 55, and 57) has an upper cavity CVTY located above the wafer product, and can also have a lower cavity located below the wafer product.

Specifically, when forming the thick resin film 20, the mold 51 (53, 55, and 57) can be used to form a resin body on the first principal face 42b of the base substrate 41. Further, when forming the thick resin film 20, the mold 51 (53, 55, and 57) can be used to form a resin body on the second principal face 42c of the base substrate 41. With these resin formation, forming the resin body on the base substrate 41 using the mold 51 (53, 55, and 57) can provide the first resin thick film 26 (and the second resin thick film 30).

Forming the resin structure 24 on the base substrate 41, specifically, the wafer product 40e, can include the following steps: loading the wafer product 40e in the mold 51 (53, 55, 57); and forming the resin structure 24 on the wafer product 40e using the mold 51 (53, 55, and 57).

The molds (53, 55, and 57) may have hanging walls (53b, 55b, and 57b), respectively. The hanging walls (53b, 55b, and 57b) define a cavity CVTY. The hanging walls (53b, 55b, 57b) each are also configured to form the resin structure 24 having a structure 28, such as a recess or groove. The structure 28 may extend in at least one of a first direction (e.g., the X direction) and a second direction (e.g., the Y direction), which may be associated with the arrangement of sections 40.

As shown in FIG. 19, the cavity CVTY can be provided for each of the sections 40 shown in FIG. 17.

In step S201, the wafer product 40e is loaded into the mold 53 (51). In step S202, molten resin is injected into the mold 53 (51) to form at least one of the first and second resin thick films 26 and 30 on the base substrate 41, for example, the first resin thick film 26 in the present disclosure. In step S203, the molded product is taken out from the mold 53 (51) to obtain a wafer product 40i.

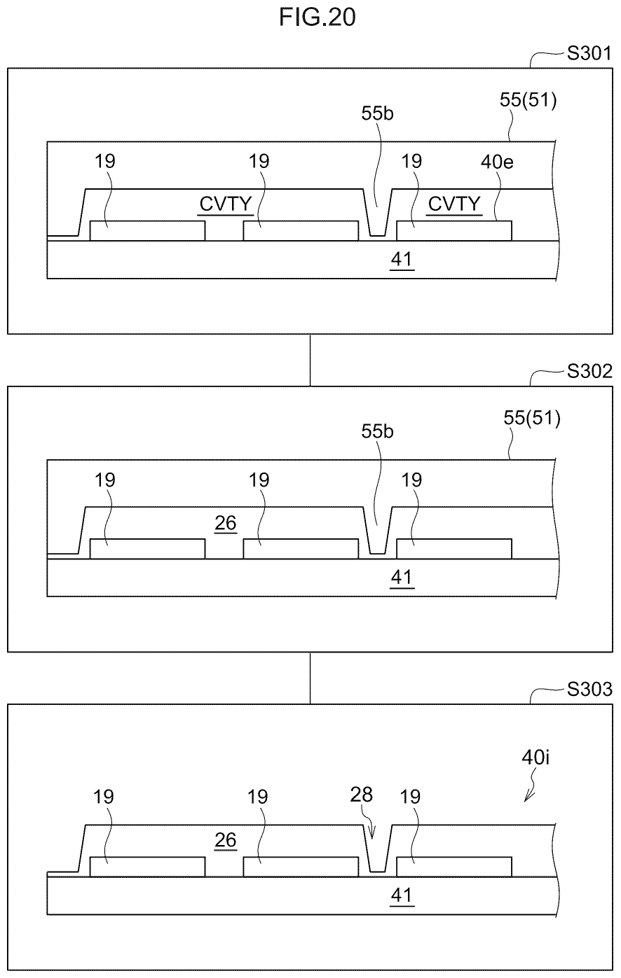

As shown in FIG. 20, the cavity CVTY may be configured to receive adjoining sections 40 of the multiple sections 40 shown in FIG. 17.

In step S301, the wafer product 40e is loaded into in the mold 55 (51). In step S302, molten resin is injected into the cavity of the mold 53 (51) to form at least one of the first and second resin thick films 26 and 30 on the base substrate 41, for example, the first resin thick film 26 in the present disclosure. In step S303, the molded product is taken out from the mold 55 (51) to obtain the wafer product 40i.

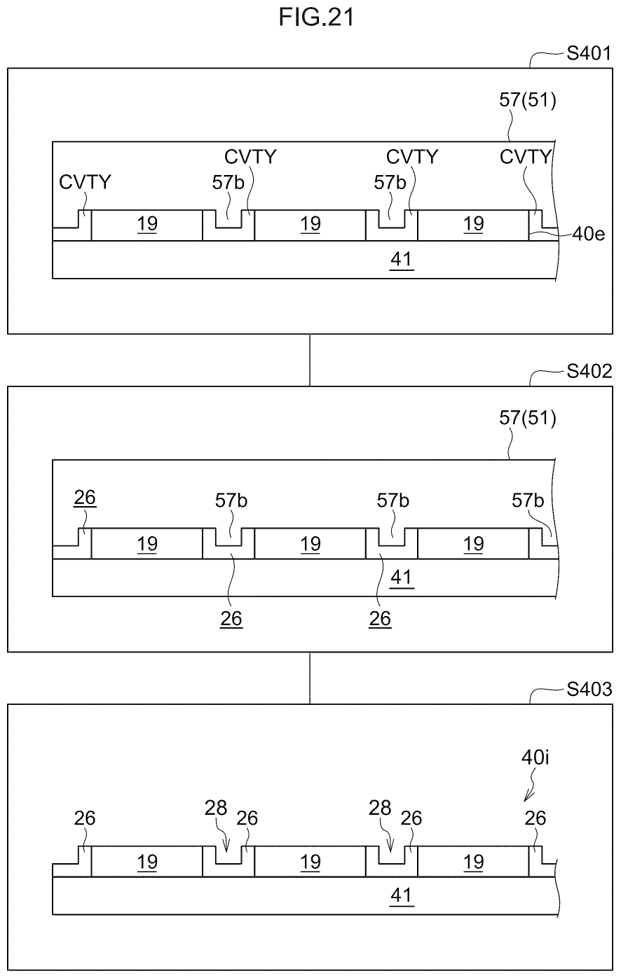

As shown in FIG. 21, the cavity CVTY may have a ceiling that is adjusted to the height of the metal thick film in each of the sections 40 shown in FIG. 17.

In step S401, the wafer product 40e is loaded into the resin mold 57 (51). In step S402, molten resin is injected into the cavity of the mold 57 (51) to form at least one of the first and second resin thick films 26 and 30 on the base substrate 41, for example, the first resin thick film 26 in the present disclosure. In step S403, the molded product is taken out from the mold 55 (51) to obtain the wafer product 40i.

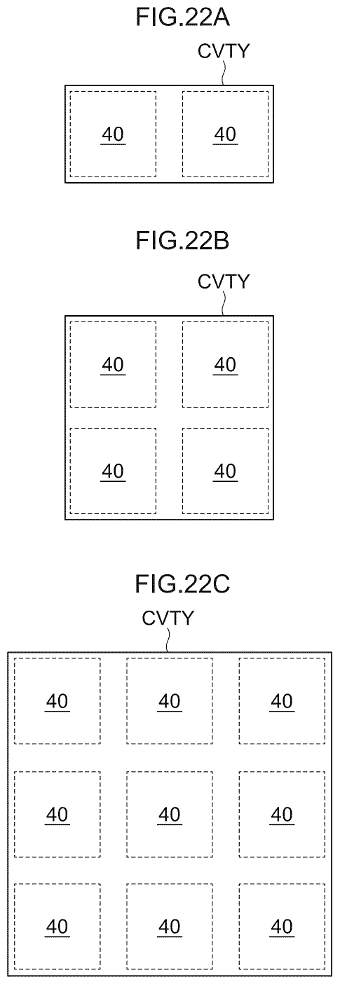

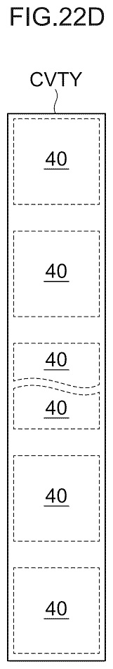

FIGS. 22A to 22D each show the size of the cavity for the exemplary resin mold 51 (53, 55, and 57) in the fabricating method according to the present disclosure.

As shown in FIG. 22A, the cavity CVTY can be determined to receive two adjoining sections 40. Flow of resin can be introduced in the direction in which the adjoining sections 40 are disposed. The arrangement of the two adjoining sections 40 allows the relaxation of the stress of the resin.

As shown in FIGS. 22B, the cavity CVTY can be determined to receive four adjacent sections 40. The arrangement of the four adjacent sections 40 allows the relaxation of the stress of the resin.

As shown in FIG. 22C, the cavity CVTY can be determined to receive nine adjacent sections 40. The arrangement of the nine adjacent sections 40 allows the relaxation of the stress of the resin.

As shown in FIG. 22D, the cavity CVTY can be determined to receive multiple sections 40 arranged in one direction. Flow of resin can be introduced in the array direction. The arrangement of the sections 40 in a row allows the relaxation of the stress of the resin.

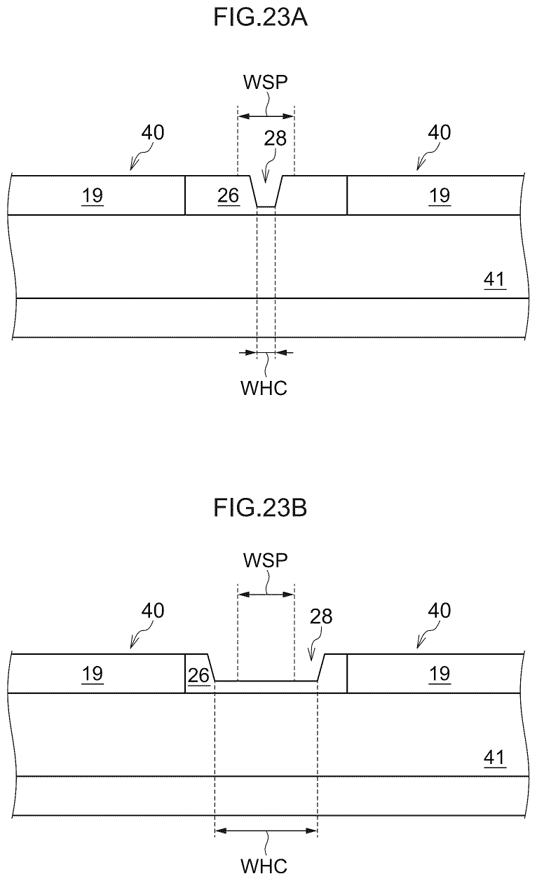

FIGS. 23A and 23B are drawings each showing an exemplary width of the half-cut region in the fabricating method according to the present disclosure, and an exemplary width of the separation region of the array in a wafer product. Referring to FIG. 23A, the width WHC of the half-cut area is smaller than the width WSP of the separation area. In the semiconductor device 11 thus fabricated, the first region 19b is not left, but the semiconductor device 11 has a reduced stress. Referring to FIG. 23B, the width WHC of the half-cut region is greater than the width WSP of the separation region. In the semiconductor device 11 thus fabricated, the first region 19b is left, and the semiconductor device 11 has a reduced stress.

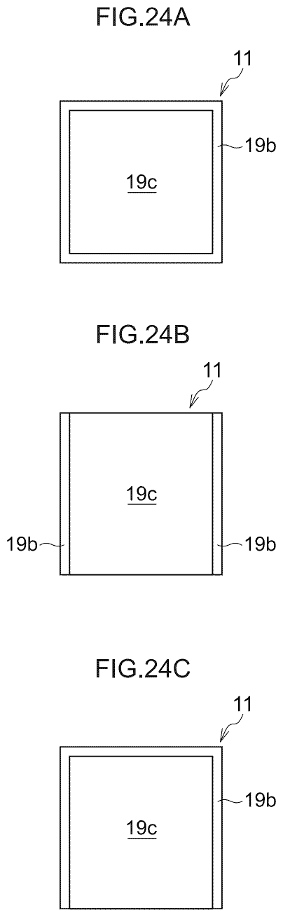

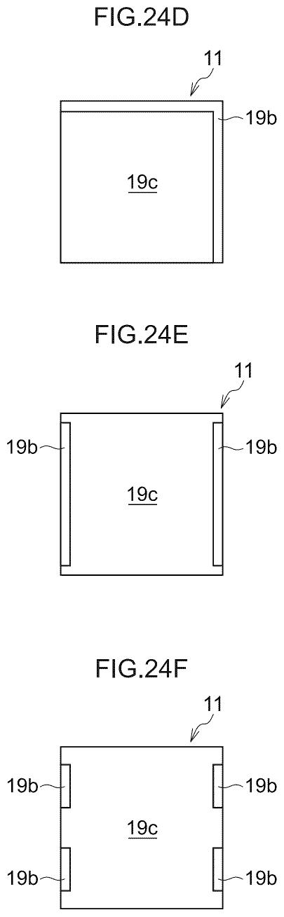

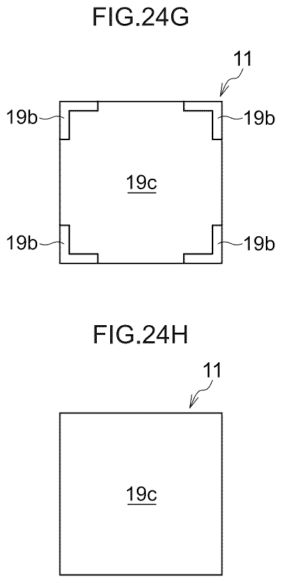

FIGS. 24A to 24H each show an exemplary arrangement of the first and second regions of a semiconductor device fabricated by the fabricating method according to the present disclosure.

Referring to FIG. 24A, the semiconductor device 11 fabricated by the above method allows the first region 19b to surround or encircle the second region 19c. This surrounding or encircling region can prevent the second region 19c from extending in two directions.

Referring to FIG. 24B, the semiconductor device 11 may be fabricated by the above method, and the first region 19b is disposed on two edges 13k opposed to each other. This structure can prevent the second region 19c from extending in one direction and allows the resin to flow in other directions.

Referring to FIG. 24C, the semiconductor device 11 may be fabricated by the above method, and the first region 19b is disposed on three adjoining edges 13k to adjoin the second region 19c on its three sides. This structure can prevent the second region 19c from extending in two directions.

Referring to FIG. 24D, the semiconductor device 11 may be fabricated by the above method, and the first region 19b is disposed on two adjoining edges 13k to adjoin the second region 19c on its two sides. This structure prevents the second region 19c from extending in the two directions.

Referring to FIG. 24E, the semiconductor device 11 may be fabricated by the above method, and the first region 19b is disposed on a part of each of the two edges 13k opposed to each other to adjoin the second region 19c on its two opposed sides. This structure can prevent the second region 19c from extending widely in one direction.

Referring to FIG. 24F, the semiconductor device 11 may be fabricated by the above method, and the first region 19b is disposed on multiple parts of each of the edges 13k opposed to each other such that the second region 19c is located between these multiple parts. This structure can prevent the second region 19c from extending to the edge of one section and allows resin to flow in the two directions.

Referring to FIG. 24G, the semiconductor device 11 may be fabricated by the above method, and the first region 19b is disposed at the four corners of the section to separate the second region 19c at each edge of the section into portions between the adjacent two corners. This structure can prevent the second region 19c from extending entirely along each edge of the section and allows resin to flow in the two directions.

Referring to FIG. 24H, the semiconductor device 11 does not include the first region 19b but the second region 19c. The semiconductor device 11 of this form can be produced from a resin-molded product, which is formed using a mold having a cavity of FIG. 22C and separated as shown in FIG. 23A. The semiconductor device 11 has a reduced stress.

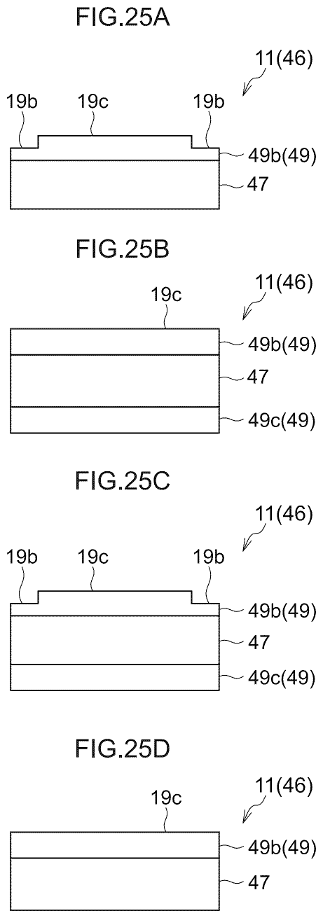

FIGS. 25A, 25B, 25C, and 25D are schematic drawings showing various CSP assemblies fabricated by the fabricating method according to the present disclosure.

As shown in FIG. 13, an array of sections 40 of the wafer product 40g is separated into CSP assemblies. This completes the CSP assembly 46.

Referring to FIG. 25A to 25D, the semiconductor device 11 is provided with the CSP assembly 46. In the CSP assembly 46, the resin structure 24 is mounted on the semiconductor chip. The first resin body 19 is disposed on the semiconductor chip, specifically, on the front side of the semiconductor chip. Further, the second resin body 25 may be disposed on the semiconductor chip, specifically, on the back side of the semiconductor chip.

As shown in FIGS. 25A to 25D, the CSP assembly 46 may include a semiconductor chip 47 including a semiconductor element in the section 40, and a resin package 49 disposed on the semiconductor chip 47. The resin package 49 is provided with the resin structure 24 on the semiconductor chip 47, and the resin structure 24 does not cover the side face 13s at the edge 13k of the supporting body 13.

The resin package 49 includes a first package 49b that covers the semiconductor element, which is located on the front side of the semiconductor chip 47. The resin package 49 may include a second package resin body 49c that covers the back side of the semiconductor chip 47.

Referring to FIGS. 25A to 25C, the first package resin body 49b is provided with the first region 19b as shown in FIGS. 24A to 24G. Referring to FIGS. 25B to 25D, the first package resin body 49b is not provided with the first region 19b as shown in FIG. 24H.

As seen from the above description, the first package resin body 49b of FIGS. 25A to 25D may be formed from the first resin thick film 26. The second package resin body 49c of FIGS. 25B and 25C may be formed from the second resin thick film 30.

As shown in FIGS. 25B and 25C, the semiconductor chip 47 is provided between the first and second package resin bodies 49b and 49c.

The present disclosure can provide a semiconductor device of a CSP structure that can reduce the warpage thereof and a method for fabricating the same, and can have various embodiments as shown below.

A semiconductor device of the first embodiment according to the present disclosure includes: a supporting body having a first principal face, a second principal face opposite to the first principal face, and one or more semiconductor elements; at least one thin film metal electrode disposed on the first principal face of the supporting body; a thick film metal body disposed on the at least one thin film metal electrode; and a resin structure disposed on the supporting body, wherein the thick film metal body has a thickness greater than that of the thin film metal electrode, wherein the resin structure includes a first resin body that covers a side of the thick film metal body on the first principal face of the supporting body, and wherein the resin structure has at least one of structures 1 and 2 as follows: in the structure 1, the resin structure further includes a second resin body on the second principal face of the supporting body; and in the structure 2, the first resin body of the resin structure includes a first region and a second region on the first principal face of the supporting body, and the second region has a thickness greater than that of the first region.

In the second embodiment according to the first embodiment of the present disclosure, the supporting body further includes an edge that defines the first principal face of the supporting body, the resin structure is provided with the first and second resin bodies, the first resin body includes the first and second regions, and the supporting body has a side face at the edge and the side face of the supporting body is not covered with the first and second resin bodies.

In the third embodiment according to the first embodiment of the present disclosure, the supporting body further includes an edge that defines the first principal face of the supporting body, the resin structure includes the first and second resin bodies without the first and second regions of the first resin body, and the supporting body has a side face at the edge and the side face of the supporting body is not covered with the first and second resin bodies.

In the fourth embodiment according to the first embodiment of the present disclosure, the resin structure provides the first resin body with the first and second regions without the second resin body.

In the fifth embodiment according to any one of the first to fourth embodiments of the present disclosure, the first principal face of the supporting body is defined by a first side and a second side that extend in a first direction, and a third side and a fourth side that extend in a second direction intersecting the first direction, and wherein the first region of the first resin body is provided along at least one side of the first, second, third, and fourth sides.

In the sixth and seventh embodiments according to any one of the first to fifth embodiments of the present disclosure, the first region has an annular loop shape to surround the second region.

A method for fabricating a semiconductor device of the eighth embodiment of the present disclosure includes: preparing a base substrate including a semiconductor, the base substrate having a first principal face, a second principal face opposite to the first principal face, and an arrangement of multiple sections, and each of the multiple sections including semiconductor elements on the first principal face; forming a thin film metal electrode on the first principal face in each of the multiple sections of the base substrate; forming a thick metal film on the first principal face in each of the multiple sections of the base substrate to form a wafer product, the thick metal film being disposed on the thin film metal electrode; and forming a resin body on the base substrate of the wafer product, the resin body including at least one resin thick film, wherein a thickness of the thick film metal body is greater than that of the thin film metal electrode, wherein the resin body includes a first resin film that covers at least a side face of the thick film metal body on the first principal face of the base substrate, and wherein the resin body has at least one of structures 1 and 2 as follows: in the structure 1, the resin body further includes a second resin thick film disposed on the second principal face of the base substrate; and in the structure 2, the resin body provides the first resin thick film with a first region and a second region, a thickness of the second region is greater than that of the first region, the first and second regions are disposed on the first principal face of the base substrate such that the first region has a shape of at least one of a recess and a groove in the first resin thick film.

In the method of the ninth embodiment according to the eighth embodiment of the present disclosure, forming a resin body on the base substrate of the wafer product includes half-cutting the at least one resin thick film of the resin body to form at least one of the recess and the groove.

In the method of the tenth embodiment according to the ninth embodiment of the present disclosure, half-cutting the at least one resin thick film of the resin body to form at least one of a recess and a groove is performed at a boundary of the multiple sections.

In the method of the eleventh embodiment according to the tenth or ninth embodiment of the present disclosure, the arrangement of multiple sections includes multiple boundaries that separate adjacent sections of the multiple sections from each other, and half-cutting the at least one resin thick film of the resin body to form at least one of a recess and a groove is performed along at least one of the boundaries to form the groove.

In the method of the twelfth embodiment according to the ninth embodiment of the present disclosure, forming a resin body on the base substrate of the wafer product includes disposing the wafer product in a mold having at least one cavity to receive one or more sections of the multiple sections, and forming the resin body on the base substrate using the mold.

In the method of the thirteenth embodiment according to the twelfth embodiment of the present disclosure, the mold has a hanging partition wall configured to define the at least one cavity, and the hanging partition wall forms the at least one of the recess or groove in the first thick resin film.

In the method of the fourteenth embodiment according to the twelfth or twelfth embodiment of the present disclosure, the cavity is shaped to receive multiple sections of the arrangement that are adjacent to each other.

In the method of the fifteenth embodiment according to the eleventh or twelfth embodiment of the present disclosure, the cavity is prepared for each section of the multiple sections.

In the method of the sixteenth embodiment according to any one of the twelfth to fifteenth embodiments of the present disclosure, the resin body is formed on the first principal face of the base substrate in the mold.

In the method of the seventeenth embodiment according to any one of the twelfth to sixteenth embodiments of the present disclosure, the resin body is formed on the second principal face of the base substrate in the mold.

The method of the eighteenth embodiment according to any one of the ninth to seventeenth embodiments of the present disclosure further includes grinding the resin thick film and the metal thick film to produce a thick film resin body and a thick film metal body from the resin thick film and the metal thick film, respectively, wherein the thick metal film, the thin metal electrode, and the base substrate are arranged in the direction of a first axis, and wherein the top faces of the thick metal film and thick resin film extend along a reference plane intersecting the first axis.

The method according to the nineteenth embodiment according to the eighteenth embodiment of the present disclosure further includes, after grinding the resin thick film and the metal thick film, separating the multiple sections from each other to form CSP assemblies, each of which includes a semiconductor chip and a resin package mounted on the semiconductor chip, wherein the semiconductor chip includes a semiconductor element that has been formed in each of the multiple sections, wherein the resin package has a resin structure on a first principal face of the semiconductor chip to prevent the resin package from covering a side face of the semiconductor chip, and wherein the resin structure includes a first resin body that covers at least a side face of the thick film metal body.

A semiconductor device of the twentieth embodiment of the present disclosure includes: a base substrate including a semiconductor region having a first principal face and a second principal face opposite to the first principal face, multiple sections arranged on the first principal face, and one or more semiconductor elements on the first principal face of the semiconductor region in each of the multiple sections; at least one thin film metal electrode disposed on the first principal face in each of the multiple sections; a thick film metal body disposed on the at least one thin film metal electrode in each of the multiple sections; and a resin body disposed on the first principal face over the multiple sections, wherein the thick film metal body has a thickness greater than that of the thin film metal electrode, wherein the resin body includes a first resin thick film that covers a side of the thick film metal body on the first principal face of the base substrate 41, and wherein the resin body has at least one of structures 1 and 2 as follows: in the structure 1, the resin body further includes a second resin thick film disposed on the second principal face of the base substrate; and in the structure 2, the resin body provides the first resin thick film with a first region and a second region, the second region has a thickness greater than that of the first region, the first and second regions are arranged on the first principal face of the base substrate to form at least one of a recess and a groove in the first resin thick film.

The present invention is not limited to the disclosures described above, and can be implemented with various changes without departing from the spirit of the present disclosure. All of these are included in the technical idea of the present disclosure.

What is claimed is:

1. A semiconductor device including:
a supporting body having a first principal face, a second principal face opposite to the first principal face, and one or more semiconductor elements;
at least one thin film metal electrode disposed on the first principal face of the supporting body;
a thick film metal body disposed on the at least one thin film metal electrode; and
a resin structure disposed on the supporting body,
wherein the thick film metal body has a thickness greater than that of the thin film metal electrode,
wherein the resin structure includes a first resin body that covers a side of the thick film metal body on the first principal face of the supporting body, and
wherein the resin structure has at least one of structures 1 and 2 as follows:
in the structure 1, the resin structure further includes a second resin body on the second principal face of the supporting body; and
in the structure 2, the first resin body of the resin structure includes a first region and a second region on the first principal face of the supporting body, and the second region has a thickness greater than that of the first region.

2. The semiconductor device according to claim 1,
wherein the supporting body further includes an edge that defines the first principal face of the supporting body,
wherein the resin structure is provided with the first and second resin bodies,
wherein the first resin body includes the first and second regions, and
wherein the supporting body has a side face at the edge and the side face of the supporting body is not covered with the first and second resin bodies.

3. The semiconductor device according to claim 1,
wherein the supporting body further includes an edge that defines the first principal face of the supporting body,
wherein the resin structure includes the first and second resin bodies without the first and second regions of the first resin body, and
wherein the supporting body has a side face at the edge and the side face of the supporting body is not covered with the first and second resin bodies.

4. The semiconductor device according to claim 1,
wherein the resin structure provides the first resin body with the first and second regions without the second resin body.

5. The semiconductor device according to claim 4,
wherein the first principal face of the supporting body is defined by a first side and a second side that extend in a first direction, and a third side and a fourth side that extend in a second direction intersecting the first direction, and
wherein the first region of the first resin body is provided along at least one side of the first, second, third, and fourth sides.

6. The semiconductor device according to claim 2,
wherein the first region has an annular closed loop shape to surround the second region.

7. The semiconductor device according to claim 4,
wherein the first region has an annular closed loop shape to surround the second region.

8. A method of fabricating a semiconductor device, including:
preparing a base substrate including a semiconductor, the base substrate having a first principal face, a second principal face opposite to the first principal face, and an arrangement of multiple sections, and each of the multiple sections including semiconductor elements on the first principal face;
forming a thin film metal electrode on the first principal face in each of the multiple sections of the base substrate;
forming a thick metal film on the first principal face in each of the multiple sections of the base substrate to form a wafer product, the thick metal film being disposed on the thin film metal electrode; and
forming a resin body on the base substrate of the wafer product, the resin body including at least one resin thick film,
wherein a thickness of the thick film metal body is greater than that of the thin film metal electrode,
wherein the resin body includes a first resin thick film that covers at least a side face of the thick film metal body on the first principal face of the base substrate, and
wherein the resin body has at least one of structures 1 and 2 as follows:
in the structure 1, the resin body further includes a second resin thick film disposed on the second principal face of the base substrate; and
in the structure 2, the resin body provides the first resin thick film with a first region and a second region, a thickness of the second region is greater than that of the first region, the first and second regions are disposed on the first principal face of the base substrate such that the first region has a shape of at least one of a recess and a groove in the first resin thick film.

9. The method according to claim 8, wherein forming a resin body on the base substrate of the wafer product includes half-cutting the at least one resin thick film of the resin body to form at least one of the recess and the groove.

10. The method according to claim 9, wherein half-cutting the at least one resin thick film of the resin body to form at least one of a recess and a groove is performed at a boundary of the multiple sections.

11. The method according to claim 9, wherein the arrangement of multiple sections includes multiple boundaries that separate adjacent sections of the multiple sections from each other, and half-cutting the at least one resin thick film of the resin body to form at least one of a recess and a groove is performed along at least one of the boundaries to form the groove.

12. The method according to claim 9, wherein forming a resin body on the base substrate of the wafer product includes disposing the wafer product in a mold having at least one cavity to receive one or more sections of the multiple sections, and forming the resin body on the base substrate using the mold.

13. The method according to claim 12, wherein the mold has a hanging partition wall configured to define the at least one cavity, and the hanging partition wall forms the at least one of the recess or groove in the first thick resin film.

14. The method according to claim 12, wherein the cavity is shaped to receive multiple sections of the arrangement that are adjacent to each other.

15. The method according to claim 12, wherein the cavity is prepared for each section of the multiple sections.

16. The method according to claim 12, wherein the resin body is formed on the first principal face of the base substrate in the mold.

17. The method according to claim 16, wherein the resin body is formed on the second principal face of the base substrate in the mold.

18. The method according to claim 9, further including grinding the resin thick film and the metal thick film to produce a thick film resin body and a thick film metal body from the resin thick film and the metal thick film, respectively,
wherein the thick metal film, the thin metal electrode, and the base substrate are arranged in the direction of a first axis, and
wherein the top faces of the thick metal film and thick resin film extend along a reference plane intersecting the first axis.

19. The method according to claim 18, further including, after grinding the resin thick film and the metal thick film, separating the multiple sections from each other to form CSP assemblies, each of which includes a semiconductor chip and a resin package mounted on the semiconductor chip, wherein the semiconductor chip includes a semiconductor element that has been formed in each of the multiple sections,
wherein the resin package has a resin structure on a first principal face of the semiconductor chip to prevent the resin package from covering a side face of the semiconductor chip, and
wherein the resin structure includes a first resin body that covers at least a side face of the thick film metal body.

20. A semiconductor device including:
a base substrate including a semiconductor region having a first principal face and a second principal face opposite to the first principal face, multiple sections arranged on the first principal face, and one or more semiconductor elements on the first principal face of the semiconductor region in each of the multiple sections;
at least one thin film metal electrode disposed on the first principal face in each of the multiple sections;
a thick film metal body disposed on the at least one thin film metal electrode in each of the multiple sections; and
a resin body disposed on the first principal face over the multiple sections,
wherein the thick film metal body has a thickness greater than that of the thin film metal electrode,
wherein the resin body includes a first resin thick film that covers a side of the thick film metal body on the first principal face of the base substrate 41,
wherein the resin body has at least one of structures 1 and 2 as follows:
in the structure 1, the resin body further includes a second resin thick film disposed on the second principal face of the base substrate; and
in the structure 2, the resin body provides the first resin thick film with a first region and a second region, the second region has a thickness greater than that of the first region, the first and second regions are arranged on the first principal face of the base substrate to form at least one of a recess and a groove in the first resin thick film.
